(19) United States
(12) Patent Application Publication
(10) Pub. No.: US 2022/0076700 A1
(43) Pub. Date: Mar. 10, 2022

(54) DATA MANAGEMENT METHOD FOR MAGNETIC DISK DEVICE AND MAGNETIC DISK DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventor: Masaya SUZUKI, Kiyose Tokyo (JP)

(21) Appl. No.: 17/374,933

(22) Filed: Jul. 13, 2021

(30) Foreign Application Priority Data
Sep. 7, 2020 (JP) 2020-149961

(51) Int. Cl. G11B 20/10; G11B 20/18

(52) U.S. Cl. CPC G11B 20/10388; G11B 20/1037; G11B 20/18

(57) ABSTRACT

According to one embodiment, a magnetic disk device including a magnetic disk, measures an error rate of the magnetic disk, sets an area to be affected by sputtering claws generated during manufacturing of the magnetic disk based on the measured error rate, and writes reference data used for measuring the error rate to the set area. Then, the magnetic disk device manages the data written to the magnetic disk based on the error rate when reading the reference data written to the set area.

### CROSS-REFERENCE TO RELATED APPLICATIONS

This application is based upon and claims the benefit of priority from Japanese Patent Application No. 2020-149961, filed Sep. 7, 2020, the entire contents of which are incorporated herein by reference.

### FIELD

Embodiments described herein relate generally to a data management method for a magnetic disk device, and a magnetic disk device.

### BACKGROUND

In the field of magnetic disk drives, the technology to reduce noise and increase areal density by reducing the grain size of magnetic disks from the viewpoint of improving read/write characteristics, is known.

Note here that as the grain size is reduced, the thermal relaxation of the magnetic disk device deteriorates. Therefore, it is necessary to take measures against thermal relaxation while improving the read/write characteristics by reducing the grain size.

Meanwhile, in the manufacturing process of magnetic disks used in magnetic disk devices, it is necessary to physically support the magnetic disks during sputtering film deposition. Here, generally, the magnetic disks are supported by multiple claws called sputtering claws. Due to the shadowing effect of these sputtering claws, the magnetic disks around the sputtering claws decrease Sputtering film thickness to be thinned. For this reason, the area around each sputtering claw tends to have less resistance to thermal relaxation in the data area, in other words, thermal relaxation tends to deteriorate.

Thus, when thermal relaxation deteriorates, loss of data stored on the magnetic disk may occur.

An object of the embodiments is to provide a data management method for a magnetic disk device that can reduce the risk of data loss due to thermal relaxation, and such a magnetic disk device.

### BRIEF DESCRIPTION OF THE DRAWINGS

FIG. 1 is a diagram showing a configuration example of a magnetic disk device according to the first embodiment.

FIG. 2 is a diagram showing an example of a magnetic disk supported by a plurality of sputtering claws in the embodiment.

FIG. 3 is shows an example of an error rate when data is read from a magnetic disk in the embodiment.

FIG. 4 is a diagram showing an example of the change in error rate over time in the embodiment.

FIG. 5 is a flowchart showing an example of the reference data setting process in the embodiment.

FIG. 6 is a flowchart showing an example of the process of measuring the error rate in the embodiment.

FIG. 7 is a flowchart showing an example of processing at the time of write according to the second embodiment.

### DETAILED DESCRIPTION

In general, according to one embodiment, a data management method for a magnetic disk device including a magnetic disk, comprises measuring an error rate of the magnetic disk, setting an area to be affected by a sputtering claw generated during manufacturing of the magnetic disk, based on the measured error rate, writing reference data to be used for the measuring of the error rate to the set area and managing data written to the magnetic disk based on the error rate when reading the reference data written to the set area.

Embodiments will be described hereinafter with reference to the accompanying drawings. Note that the disclosure is merely an example, and the invention is not limited by the contents of the embodiments provided below. In addition, in some cases, in order to make the description clearer, the widths, thicknesses, shapes, etc., of the respective parts are schematically illustrated in the drawings, compared to the actual modes. However, the schematic illustration is merely an example, and adds no restrictions to the interpretation of the invention. Besides, in the specification and drawings, the same elements as those described in connection with preceding drawings are denoted by like reference numerals, and a detailed description thereof is omitted unless otherwise necessary.

### First Embodiment

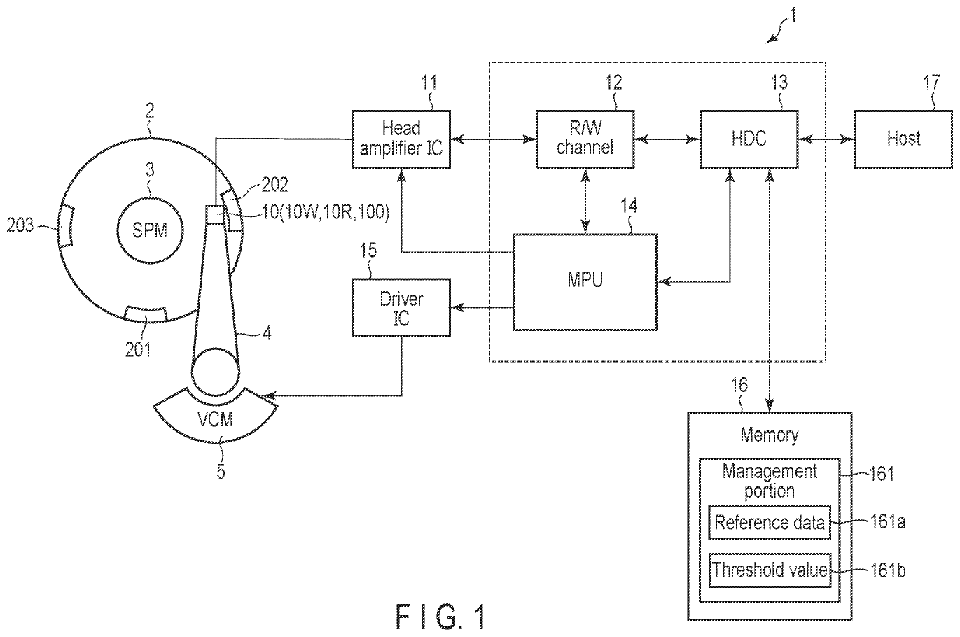

FIG. 1 is a diagram showing an example of the configuration of a magnetic disk device according to the first embodiment.

As shown in FIG. 1, a magnetic disk device 1 is configured as a hard disk drive (HDD), for example, and comprises a magnetic disk 2, a spindle motor (SPM) 3, an actuator 4, a voice coil motor (VCM) 5, a magnetic head 10, a head amplifier IC 11, a R/W channel 12, a hard disk controller (HDC) 13, a microprocessor (MPU) 14, a driver IC 15 and a memory 16. The magnetic disk drive 1 can be connected to a host computer (host) 17. The magnetic head 10 comprises a write head 10W, a read head 10R, and a spin-torque-oscillator (STO) 100. Note that the R/W channel 12, the HDC 13 and the MPU 14 may be incorporated into a single chip integrated circuit.

The magnetic disk 2 comprises a substrate formed, for example, into a disk shape and made of a non-magnetic material. On each surface of the substrate, a soft magnetic layer made of a material exhibiting soft magnetic properties as a base layer, a magnetic recording layer having magnetic anisotropy in the direction perpendicular to the disk surface on top thereof, and a protective film layer on top thereof, are stacked in the order of mentioning.

The magnetic disk 2 is fixed to the spindle motor (SPM) 3 and is rotated at a predetermined speed by the SPM 3. Note that there may be two or more magnetic disks 2 set on the SPM 3. The SPM 3 is driven by the drive current (or drive voltage) supplied from the driver IC 15. The magnetic disk 2 records and reproduces data patterns by the magnetic head 10. The magnetic disk 2 includes management areas 201 to 203. The details of the management areas 201 to 203 will be described later.

The actuator 4 is installed to be rotatable, and the magnetic head 10 is supported at a distal end portion of the actuator. By rotating the actuator 4 by the voice coil motor (VCM) 5, the magnetic head 10 is moved and positioned on a desired track of the magnetic disk 2. The VCM 5 is driven by the drive current (or drive voltage) supplied from the driver IC 15.

The magnetic head 10 comprises a slider (omitted form the figure), a write head 10W, a read head 10R, and an STO 100, formed on the slider. There may be a plurality of magnetic heads 10 provided in accordance with the number of disks 2.

The head amplifier IC 11 includes circuits related to driving of the STO 100 and detecting the oscillation characteristics, and the like. The head amplifier IC 11 executes the driving of the STO 100, the detection of drive signals and the like. Further, the head amplifier IC 11 supplies a write signal (write current) according to write data supplied from the R/W channel 12 to the write head 10W. Further, the head amplifier IC 11 amplifies a read signal output from the read head 10R and transmits it to the R/W channel 12.

The R/W channel 12 is a signal processing circuit which processes signals related to read/write. The R/W channel 12 includes a read channel which executes signal processing of read data and a write channel which executes signal processing of write data. The R/W channel 12 converts the read signal into digital data and demodulates the read data from the digital data. The R/W channel 12 encodes the write data transferred from the HDC 13 and transfers the encoded write data to the head amplifier IC 11.

The HDC 13 controls the writing of data to and reading of data from the disk 2 via the magnetic head 10, the head amplifier IC 11, the R/W channel 12 and the MPU 14. The HDC 13 constitutes an interface between the magnetic disk drive 1 and the host 17, and executes transfer control of read data and write data. Further, the HDC 13 receives commands (write commands, read commands, etc.) transferred from the host 17 and sends the received commands to the MPU 14.

The MPU 14 is a main controller of the magnetic disk drive 1 and executes the read/write operation control and the servo control necessary for positioning the magnetic head 10. The driver IC 15 controls the drive of the SPM 3 and the VCM 5 according to the control of the MPU 14. As the VCM 5 is driven, the magnetic head 10 is positioned on the target track on the disk 2.

The memory 16 includes a volatile memory and a non-volatile memory. For example, the memory 16 includes a buffer memory made from a DRAM and a flash memory. The memory 16 stores programs and parameters necessary for the processing by the MPU 14. The memory 16 also includes a management portion 161. The management portion 161 manages programs and data for managing, as management areas, areas of the magnetic disk 2 that is thinned by being supported by sputtering claws when the magnetic disk 2 is manufactured. Further, the management portion 161 stores reference data 161a and a threshold value 161b. Details of the reference data 161a and the threshold value 161b will be described later.

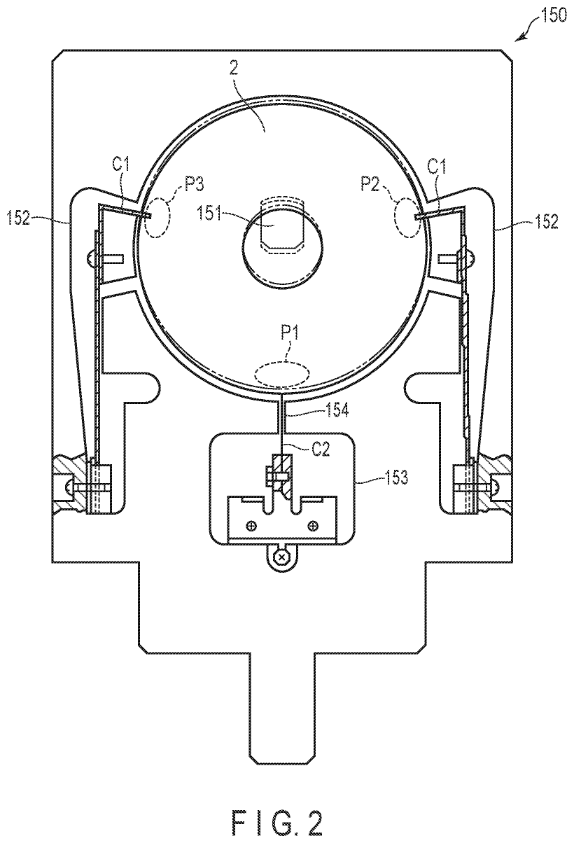

Here, the state in which the magnetic disk 2 is supported by the sputtering claws during manufacturing of the magnetic disk 2 will be described. FIG. 2 is a diagram showing an example of a magnetic disk 2 supported by the sputtering claws. In FIG. 2, openings 152 are provided on respective sides of the base 150, and sputtering claws C1 are provided on the respective openings 152. Further, a screw 153 is provided on a lower side of the base 150, and a sputtering claw C2 is provided through a bottle neck 154 on a magnetic disk 2 side with respect to the screw 153. The magnetic disk 2 is supported at three locations by the respective sputtering claws C1 and the claw C2. The areas to be thinned by the sputtering claws C1 are areas P2 and P3, and the area to be thinned by the sputtering claw C2 is an area P1. The position and number of sputtering claws shown in FIG. 2 is only an example, and is not limited to this.

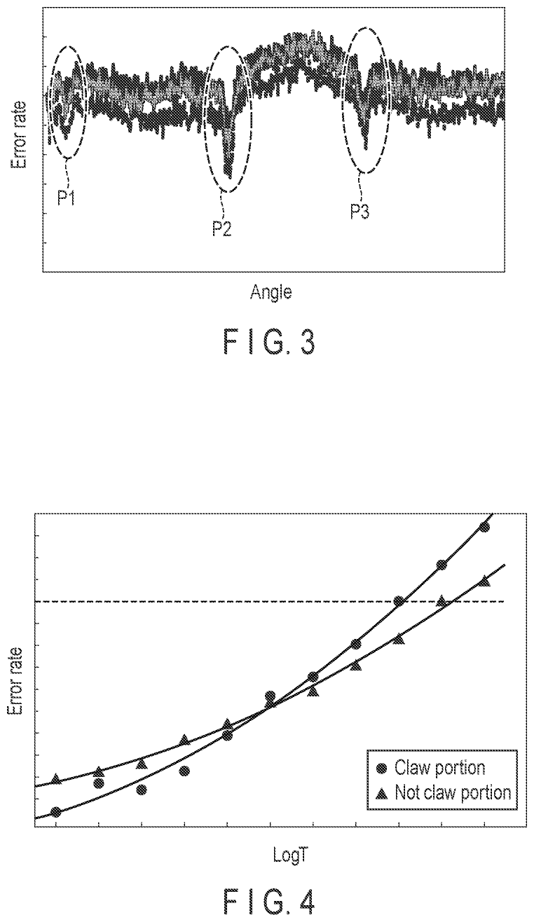

FIG. 3 is a diagram showing an example of the error rate when data is read from the magnetic disk 2, which is manufactured using the base 150 shown in FIG. 2. In FIG. 3, the horizontal axis indicates the angle, and the vertical axis indicates the error rate. The data in FIG. 3 indicates the bit error rates at the three locations on a radial outer side of the magnetic disk 2. Note here that in this figure, the upper the locations as compared to the lower side, the outer the area in the magnetic disk 2.

As the error rate is lower, the quality of read/write becomes better. As shown in FIG. 3, in each of the areas P1 to P3 corresponding to the positions of the sputtering claws C1 and C2, the error rate is low. In this manner, the error rate is measured, and based on the measurement results, the areas corresponding to the areas P1, P2 and P3 where the error rate is low is set in the management portion 161 as the management areas 201 to 203. This process is set, for example, at the time of inspection before shipping of the magnetic disk device 1 in which the magnetic disk 2 is incorporated.

Further, at the time of the inspection, the process of writing the reference data used for management of the management areas 201 to 203 after the shipping of the magnetic disk drive 1, to the management areas 201 to 203, is executed. The reference data is stored in the management portion 161 as reference data 161a and is also recorded in the management areas 201 to 203 of the magnetic disk 2. Furthermore, in this embodiment, the management areas 201 to 203 are set to be prohibited to be used as storage areas for data by the user.

Further, in the management portion 161 of the memory 16, a threshold value which indicates that the error rate calculated by reading the reference data from the management areas 201 to 203 is the unrecoverable error limit, is set.

FIG. 4 is a diagram showing an example of the change in error rate over time. In FIG. 4, the horizontal axis indicates the log of time, and the vertical axis indicates the error rate. The sputtering claw areas (management area 201 to 203) and non-claw areas (data areas) are shown respectively. It is indicated that the error rate of the control areas 201 to 203 becomes higher than that of the data areas at a timing of a certain period of time elapsed. In other words, it is indicated that the thermal relaxation deteriorates faster in the control areas 201 to 203 than in the data areas. The value indicated by the broken line in the figure is the unrecoverable error limit, and this threshold is stored as a threshold value 161b in the management portion 161.

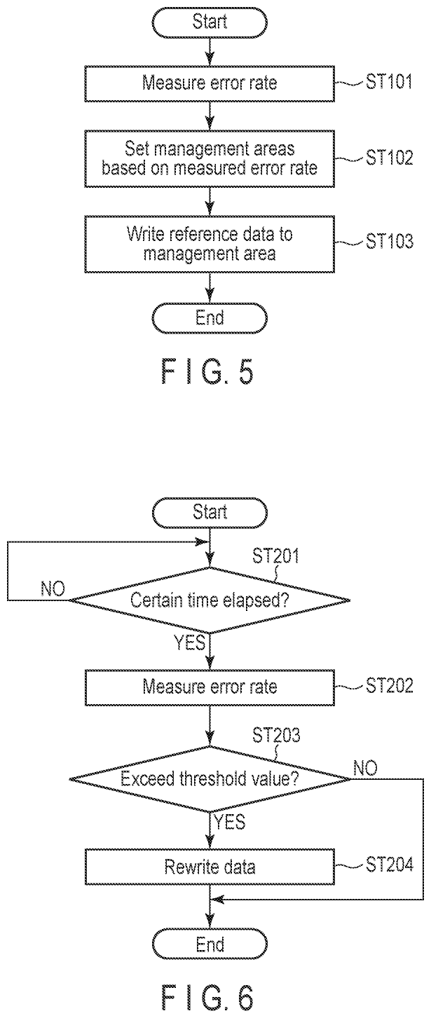

Next, the process of setting the reference data 161a before shipping the magnetic disk drive 1 will be explained. FIG. 5 is a flowchart showing an example of the process of setting the reference data 161a. In this embodiment, the MPU 14 executes the process based on the commands of the host connected to the magnetic disk drive 1.

As shown in FIG. 5, first, the MPU 14 measures the error rate of the magnetic disk 2 (ST101). In more detail, the MPU 14 writes data to the magnetic disk 2 and measures the error rate based on whether or not the data has been written correctly.

Next, the MPU 14 sets the management areas 201 to 203 based on the measured error rate (ST102). In more detail, the MPU 14 obtains the data shown in FIG. 3 above by measuring the error rate. In the case shown in FIG. 3, the areas on the magnetic disk 2 corresponding to the areas P1, P2 and P3 where the error rate is low are set as the management areas 201 to 203 in the management portion 161 of the memory 16.

Next, the MPU 14 writes the reference data 161a to an area managed by the management portion 161 (ST103). As already described, the management areas 201 to 203 sputtering film thickness to be thinned, thus making it easy to write data therein. Therefore, when writing the reference data 161a, the MPU 14 may raise the amount of levitation of the write head 10W to the recording surface of the magnetic disk 2 to above the normal setting, or may reduce the write current to the write head 10W to below the normal setting.

By executing the process described above, the reference data 161a is written to the control areas 201 to 203, and thus the magnetic disk drive 1 with the reference data 161a stored in the control areas 201 to 203 is manufactured. Note that the reference data 161a is also stored in the management portion 161.

Next, the process of the magnetic disk drive 1 that is shipped and used under the user will be described.

FIG. 6 is a flowchart showing an example of the process of measuring the error rate.

As shown in FIG. 6, the MPU 14 judges whether or not a certain time has elapsed (ST201). When the MPU 14 judges that a certain time has not yet elapsed (ST201: NO), the process returns to step ST201. In other words, after a fixed time has elapsed, the processing from step ST202 on is executed. Note that the fixed time can be set arbitrarily.

When it is judged that a certain time has elapsed (ST202: YES), the MPU 14 measures the error rate (ST202). The MPU 14 reads the reference data 161a stored in the management areas 201 to 203, and compares the thus read reference data 161a with the reference data 161a stored in the management portion 161, to calculate the error rate.

Next, the MPU 14 judges whether or not exceeding the threshold value (ST203). In more detail, the MPU 14 judges whether or not the error rate calculated by the processing of step ST202 exceeds the threshold value 161b stored in the management portion 161. When the MPU 14 judges that the error rate does not exceed the threshold value 161b (ST203: NO), the process ends.

On the other hand, if it is judged to exceed the threshold value 161b (ST203: YES), the MPU 14 executes data rewrite (ST204). More specifically, the MPU 14 executes the process of rewriting all data on the magnetic disk 2, and then finishes the process.

With the magnetic disk device 1 configured as described above, the data written to the magnetic disk 2 can be managed based on the error rate of the reference data 161a written to the management areas 201 to 203. More specifically, the magnetic disk drive 1 rewrites the data on the magnetic disk 2 when the error rate exceeds the threshold value 161b. Thus, the magnetic disk drive 1 can reduce the risk of data loss, which may be caused by thermal relaxation.

### Second Embodiment

In the above-described first embodiment, the management areas 201 to 203 are set not to be used as data areas, but this embodiment is different therefrom in that the management areas 201 to 203 can be used as data areas. The difference in configuration will now be explained in detail. The structural elements identical to those of the first embodiment above will be denoted by the same reference symbols, and a detailed explanation of the structure will be omitted.

As already described, in this embodiment, the magnetic disk drive 1 is configured so that the management areas 201 to 203 can be used as data areas. With this structure, the user can increase the area that can be used as the data area of the magnetic disk drive 1, as compared to the case of the first embodiment above. Thus, the user can store more data in the magnetic disk device 1.

Moreover, when using the management areas 201 to 203 as the data areas as in this embodiment, the following control is carried out at the time of write because the data areas are thinned.

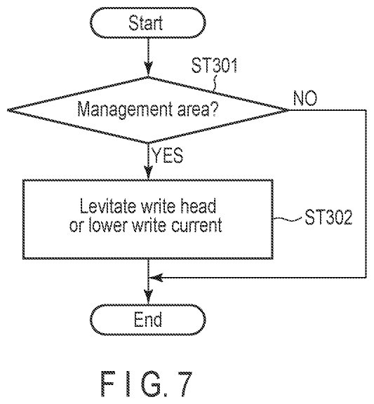

FIG. 7 is a flowchart showing an example of the processing at the time of write in this embodiment.

As shown in FIG. 7, the MPU 14 judges whether or not an area subject to write of data at the time of write is a management area (ST301). That is, the MPU 14 judges whether or not the area to which the data is to be written is one of the management areas 201 to 203. If the MPU 14 judges that it is not the management area (ST301: NO), the process terminates. Thereby, the normal write process is executed.

On the other hand, if the MPU 14 judges that it is a management area (ST301: YES), the MPU 14 raises the flying height of the write head 10R of the magnetic head 10 with respect to the recording surface of the magnetic disk 2 higher than that of the normal setting, or reduces the write current to the write head 10W lower than that of the normal setting (ST302), and this process terminates.

According to the magnetic disk drive 1 configured as described above, in addition to the advantageous effects exhibited by the above-described embodiment, the magnetic disk drive 1 can increase the area that can be used as the data area, and also execute appropriate write processing on the management portion 161.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A data management method for a magnetic disk device including a magnetic disk, the method comprising:
measuring an error rate of the magnetic disk;
setting an area affected by a sputtering claw generated during manufacturing of the magnetic disk, based on the measured error rate;
writing reference data to be used for the measuring of the error rate to the set area; and
managing data written to the magnetic disk based on the error rate when reading the reference data written to the set area.

2. The method of claim 1, wherein
the managing of the data comprises:
reading the reference data written to the set area at a predetermined timing;
measuring the error rate of the read reference data; and
rewriting, when the detected error rate exceeds a threshold value, the data written to the magnetic disk.

3. The method of claim 1, wherein
an area of the set area, other than the area where the reference data is written is not used as a data area.

4. The method of claim 1, wherein
an area of the set area, other than the area where the reference data is written is used as a data area.

5. The method of claim 4, wherein
when writing data to a data area of the set area, other than the area where the reference data is written, the amount of Flying height of a write head is higher than that of the data area other than the data area of the set area.

6. The method of claim 4, wherein
when writing data to a data area of the set area, other than the area where the reference data is written, a write current of a write head is lower than that of a data area other than the data area of the set area.

7. A magnetic disk device comprising:
a magnetic disk including an area affected by sputtering claws created during manufacturing of the magnetic disk, to which reference data used for measuring an error rate is written, based on the error rate measured from the magnetic disk; and
a control portion which manages the data written to the magnetic disk based on the error rate when reading the written reference data.
